(19) United States
(12) Patent Application Publication
(10) Pub. No.: US 2005/0156199 A1
(43) Pub. Date: Jul. 21, 2005

(54) Method of forming a CMOS device

(75) Inventors: Young-Gun Ko, Sungnam-si (KR); Sung-Gun Kang, Suwon-si (KR); Soo-Yong Lee, Yongin-si (KR); Jeong-Ho Shin, Uiwang-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/033,207

(22) Filed: Jan. 11, 2005

(30) Foreign Application Priority Data
Jan. 20, 2004 (KR) 04-4163

(51) Int. Cl. H01L 29/73; H01L 23/48; H01L 29/74

(52) U.S. Cl. 257/204; 257/760; 257/211; 257/382; 257/384; 257/369

(57) ABSTRACT

In a method of forming a CMOS device, first and second conductive structures are formed on a substrate. An insulation layer is formed on the substrate having the first and second conductive structures. The insulation layer is patterned to form an insulation layer pattern having a first portion on the first conductive structure and a second portion on the second conductive structure. The first portion has a compressive stress and functions as an etch stop layer. The second portion functions as an etch stop layer.

### CROSS REFERENCE TO RELATED APPLICATION

This application claims priority under 35 USC § 119 to Korean Patent Application No. 2004-4163, filed on Jan. 20, 2004, the contents of which are herein incorporated by reference in their entirety for all purposes.

### BACKGROUND OF THE INVENTION

1. Field of the Invention

The present invention relates to a method of forming a complementary metal-oxide-silicon (CMOS) device. More particularly, the present invention relates to a method of forming a CMOS device that includes an NMOS transistor and a PMOS transistor.

2. Description of the Related Arts

As a switching speed of semiconductor devices continues to increase at an accelerated pace, and as the threshold voltage of transistors of the semiconductor devices continues to be reduced, regular improvements to the transistor structure and fabrication approaches are required in order to improve performance of such devices.

The switching speed of the semiconductor device can be increased by improving the driving current provided to the semiconductor device. The driving current can be improved by reducing the channel length and the thickness of a gate insulation layer in the semiconductor device.

However, when the channel length and the thickness of the gate insulation layer are reduced, the off-state leakage current is increased, which in turn, can cause deterioration of device performance due to the presence of gate tunneling current. Further, to reduce the channel length, an improved exposure process and/or an improved exposure apparatus may be required, which can affect manufacturing costs. Alternatively, the driving current can be improved by increasing the mobility of carriers such as holes or electrons in a MOS transistor. In this case, the driving current can be improved, so that the switching speed can be increased, without incurring the above-mentioned limitations.

The mobility of the carriers corresponds to an average speed of the carriers that are generated by an electric field of the semiconductor device. Improving the mobility of the carriers results in improved ability to operate the semiconductor device at a low voltage as well as enhancing the switching speed of the semiconductor device.

A method of improving carrier mobility using a strained silicon layer in a channel region of a transistor is disclosed in an article presented at the “2001 symposium on VLSI technology digest of technical papers” entitled “Strained Si NMOSFETs for High-Performance CMOS Technology”.

When the method using the strained silicon layer is employed in a CMOS transistor having an NMOS transistor and a PMOS transistor, a tensile stress may be found in the NMOS transistor and the PMOS transistor. The tensile stress enhances the mobility of the carriers in the NMOS transistor, which is beneficial for increasing the driving current in the NMOS transistor. However, the tensile stress also operates to reduce the mobility of the carriers, which decreases the driving current in the PMOS transistor.

Further, as semiconductor devices become more highly integrated, the interval between devices becomes narrower so that the area in which the devices are formed is continually reduced. Thus, the vertical height of the devices has been high proportional with integration of the semiconductor device. This causes a contact region in the semiconductor device to be reduced so that a contact margin may not be sufficiently ensured. Also, the aspect ratio of the contact is greatly increased. Therefore, a process for forming a contact hole is required using an etchant having a high etching selectivity between an active region and a field region of the device and, as a result, formation of the contact hole is a difficult process. As a result, an etch stop layer plays an important role in the formation of a semiconductor device to enable formation of the contact hole.

Therefore, the strained silicon layer in the channel region of the NMOS transistor for increasing the driving current functions as the etch stop layer used for forming a contact hole. On the contrary, a layer that prevents the reduction of the driving current and simultaneously serves as the etch stop layer used for forming the contact hole in a channel region of the PMOS transistor is required.

### SUMMARY OF THE INVENTION

The present invention provides a method of forming a CMOS device that includes a PMOS transistor in which a contact hole is readily formed without reducing driving current in the device and an NMOS transistor in which a contact hole is readily formed, while providing a beneficial increase in driving current.

In a method of forming a CMOS device in accordance with one aspect of the present invention, first and second conductive structures are formed on a substrate. An insulation layer is formed on the substrate having the first and second conductive structures. The insulation layer is patterned to form an insulation layer pattern having a first portion on the first conductive structure and a second portion on the second conductive structure. The first portion has a compressive stress and functions as an etch stop layer. The second portion functions as an etch stop layer.

According to one embodiment of the present invention, the insulation layer pattern may be annealed by a rapid thermal process at a temperature of about 500° C. to about 1,000° C. Also, the insulation layer includes silicon nitride, silicon oxynitride, silicon carbide, silicon carbon nitride or a combination thereof. The insulation layer has a thickness of about 300 Å to about 700 Å.

According to another embodiment of the present invention, forming the insulation layer pattern includes forming a photoresist pattern on the insulation layer to partially expose the insulation layer, and partially etching the insulation layer using the photoresist pattern as an etching mask to form the insulation layer pattern.

According to still another embodiment of the present invention, the first conductive structure may correspond to an NMOS transistor, and the second conductive structure may correspond to a PMOS transistor.

In a method of forming a CMOS device in accordance with another aspect of the present invention, first and second conductive structures are formed on a substrate. A first insulation layer is formed on the substrate having the first and second conductive structures. The first insulation layer is patterned to form a first insulation layer pattern having a first portion on the first conductive structure and a second portion on the second conductive structure. The first portion has a compressive stress and functions as an etch stop layer. The second portion functions as an etch stop layer. A second insulation layer is formed on the substrate having the first insulation layer pattern. The second insulation layer is patterned to form a second insulation layer pattern partially exposing the first insulation layer pattern. The first insulation layer pattern is etched using the second insulation layer pattern as an etching mask to form a contact hole.

According to one embodiment of the present invention, the first insulation layer pattern may be annealed by a rapid thermal process at a temperature of about 500° C. to about 1,000° C. Also, the first insulation layer includes silicon nitride, silicon oxynitride, silicon carbide, silicon carbon nitride or a combination thereof. The first insulation layer has a thickness of about 300 Å to about 700 Å.

According to another embodiment of the present invention, forming the first insulation layer pattern includes forming a photoresist pattern on the first insulation layer to partially expose the first insulation layer, and partially etching the first insulation layer using the photoresist pattern as an etching mask to form the first insulation layer pattern.

According to still another embodiment of the present invention, the second insulation layer pattern has a critical dimension of no more than about 0.15 μm.

According to the present invention, a CMOS device includes a first insulation layer pattern that includes the first portion having a compressive stress and functioning as the etch stop layer in the NMOS transistor, and the second portion functioning as the etch stop layer in the PMOS transistor. Therefore, the contact hole may be readily formed in the PMOS transistor without reducing the driving current. Also, the contact hole may be readily formed and the driving current may be increased in the NMOS transistor.

### BRIEF DESCRIPTION OF THE DRAWINGS

The above objects and advantages of the present invention will become more apparent by describing preferred embodiments in detail with reference to the attached drawings in which:

FIG. 1 is a layout illustrating a CMOS device in accordance with an embodiment of the present invention;

FIGS. 2A to 2H are cross-sectional views illustrating a method of forming the CMOS device, the views being taken along line I-I′ in FIG. 1, in accordance with the present invention; and

FIGS. 3A to 3H are cross-sectional views illustrating a method of forming the CMOS device, the views being taken along line II-II′ in FIG. 1, in accordance with the present invention.

### DETAILED DESCRIPTION OF EMBODIMENTS

The present invention will be described more fully hereinafter with reference to the accompanying drawings, in which preferred embodiments of the invention are shown.

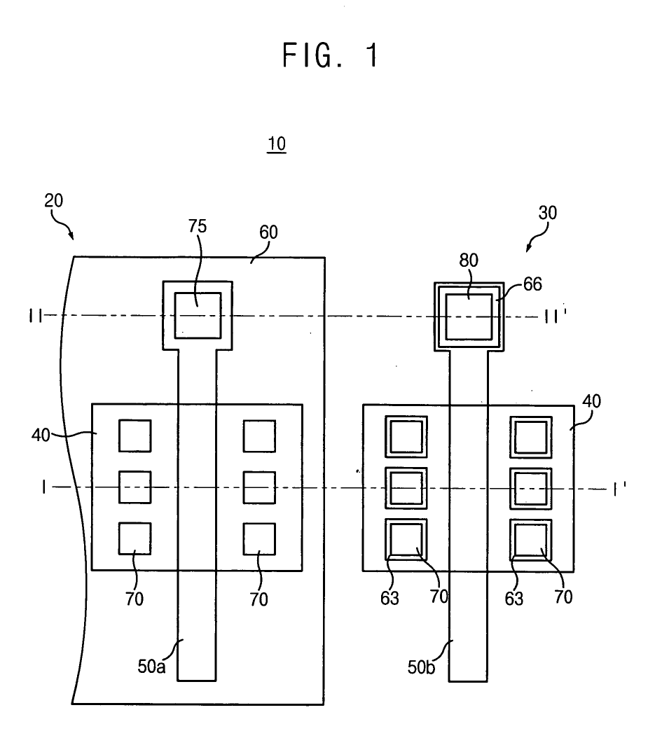

Referring to FIG. 1, a CMOS device 10 in accordance with an embodiment of the present invention includes an NMOS transistor 20 and a PMOS transistor 30.

The NMOS transistor 20 includes a first insulation layer pattern 60 formed on an active region 40 and a field region. A gate electrode 50a is formed over the active region 40 and the field region. First contact holes 70 are formed through the first insulation layer pattern 60 at both sides of the gate electrode 50a in the active region 40. A second contact hole 75 is formed through the gate electrode 50a in the field region.

The PMOS transistor 30 includes a second gate electrode 50b formed on the active region 40 and the field region. Second insulation layer patterns 63 are formed at both sides of the second gate electrode 50b in the active region 40. A third insulation layer 66 is formed on the second gate electrode 50b in the field region. Third contact holes 70 are formed through the second insulation layer pattern 63. A fourth contact hole 80 is formed through the third insulation layer pattern 66.

Hereinafter, a method of forming the CMOS device is illustrated in detail with reference to accompanying drawings.

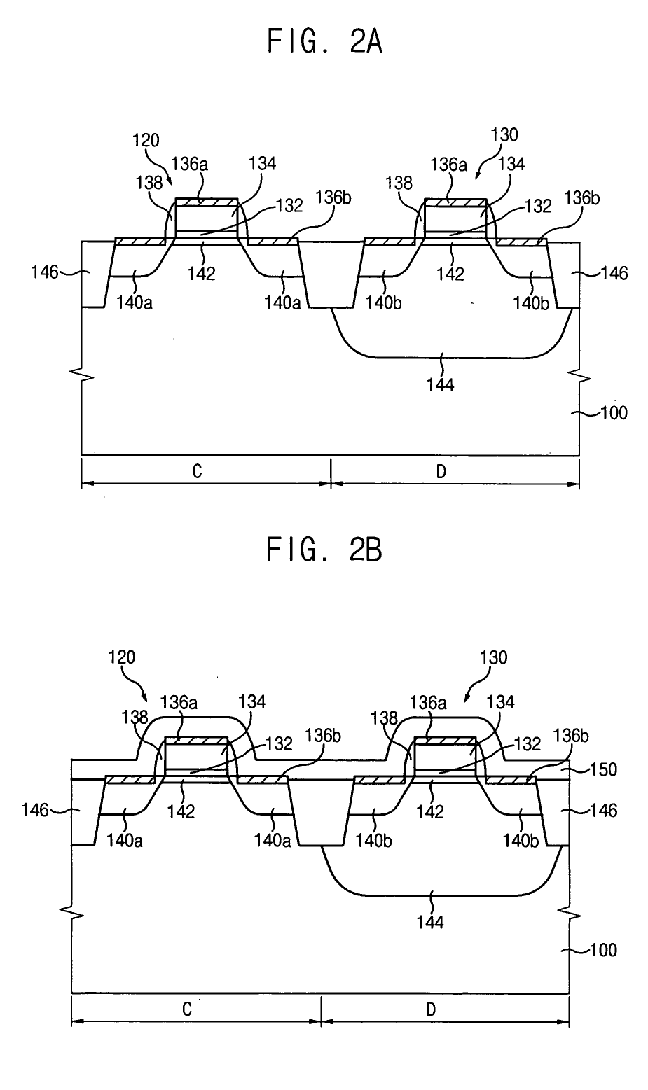

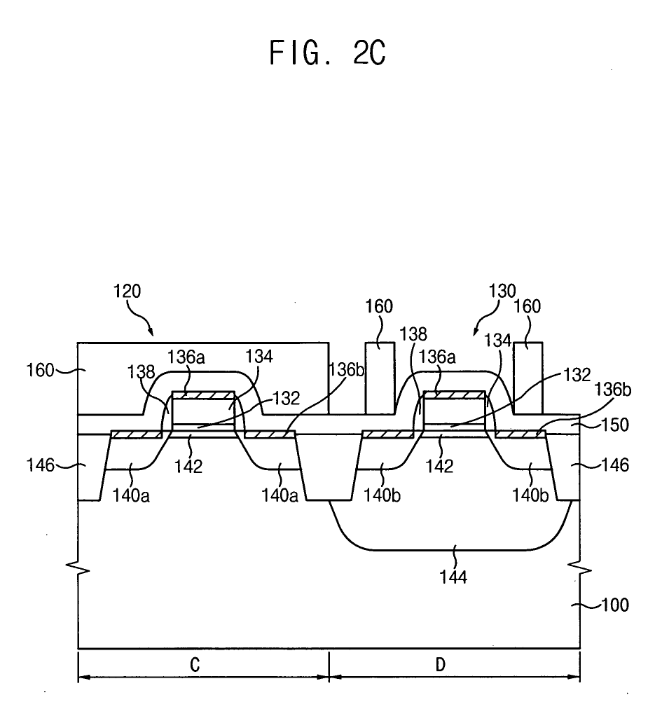

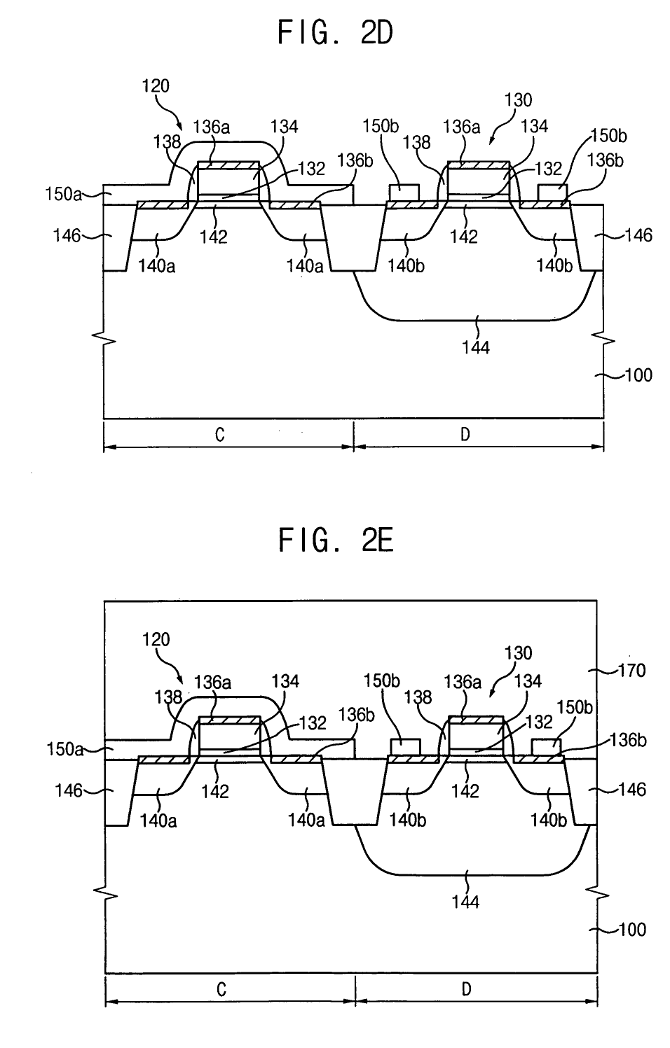

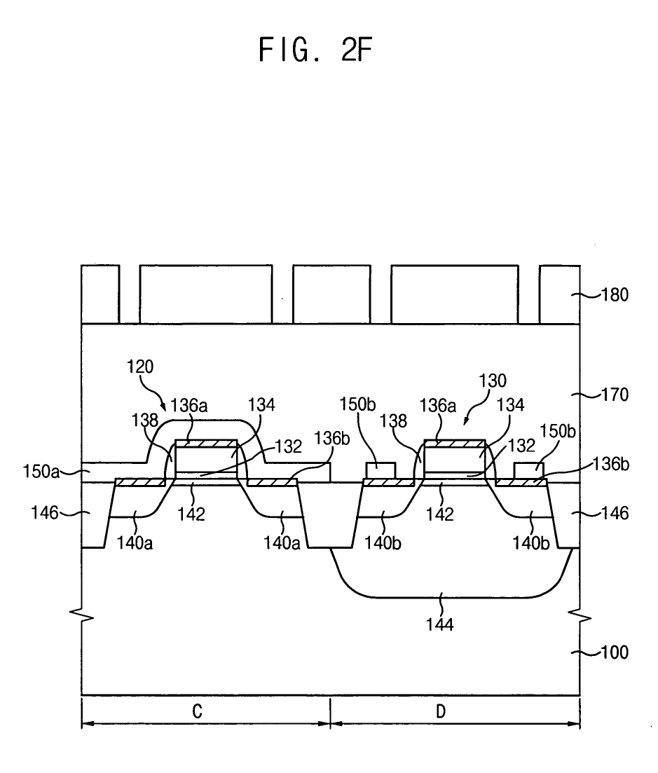

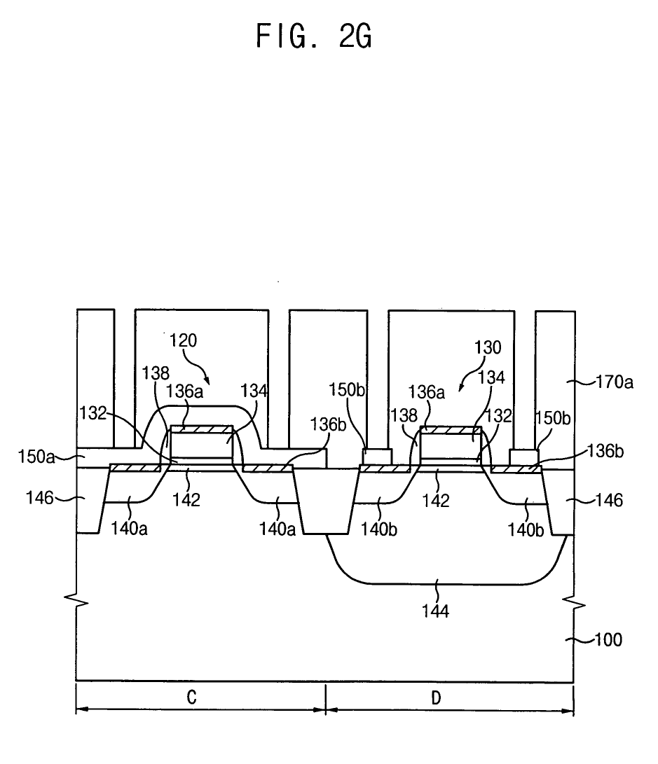

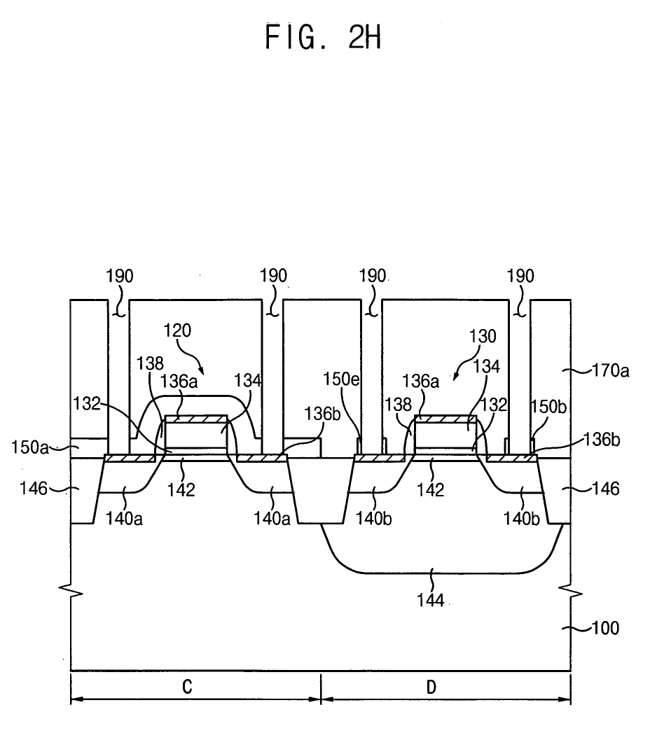

Referring to FIG. 2A, an NMOS transistor 120 is formed in a region C of a semiconductor substrate 100. A PMOS transistor 130 is formed in a region D of the semiconductor substrate 100. Each of the NMOS transistor 120 and the PMOS transistor 130 includes a gate insulation layer 132, a gate electrode 134 including polysilicon formed on the gate insulation layer 132, a first silicide layer 136a formed on the gate electrode 134, and a side wall spacer 138 formed on a sidewall of the gate electrode 134. Here, the semiconductor substrate 100 may include, for example, a silicon substrate or a silicon-on-insulator (SOI) substrate.

Source/drain regions 140a and 140b are formed in portions of the semiconductor substrate at both sides of a channel region 142 that is positioned under the gate electrode 134. A second silicide layer 136b is formed on the source/drain regions 140a and 140b.

The semiconductor substrate 100 is doped with P type impurities. The source/drain regions 140a of the NMOS transistor 120 are doped with N type impurities. An N-well 144 doped with N type impurities is formed below the PMOS transistor 130. The source/drain regions 140b of the PMOS transistor 130 are doped with P type impurities.

An isolation layer 146 such as a field oxidation region may be formed by a local oxidation of silicon (LOCOS) process or a shallow trench isolation (STI) process. The isolation layer 146 is formed between the NMOS transistor 120 and the PMOS transistor 130 to electrically isolate the NMOS transistor 120 and the PMOS transistor 130 from each other.

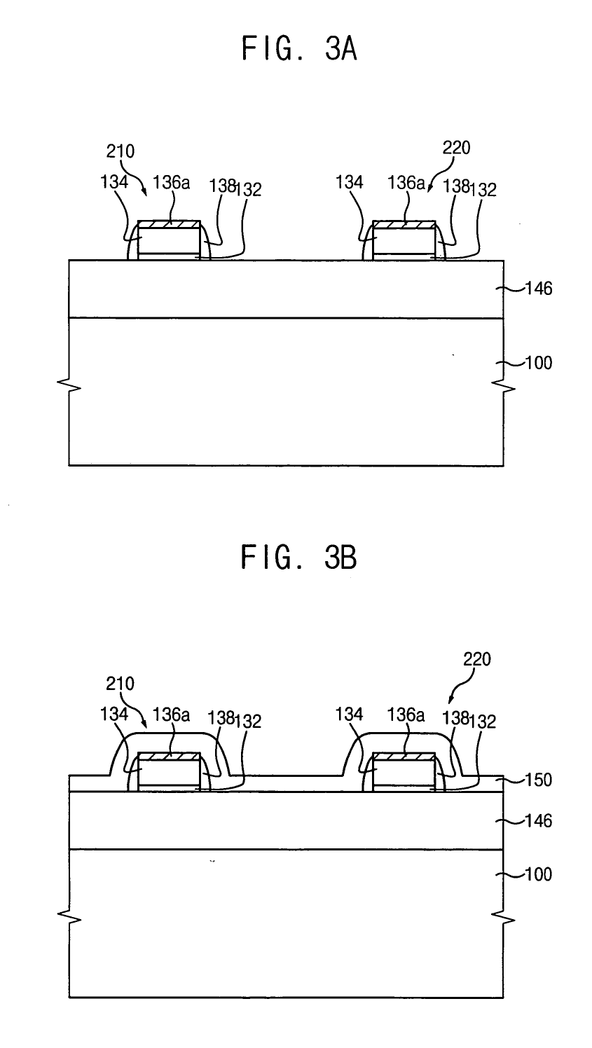

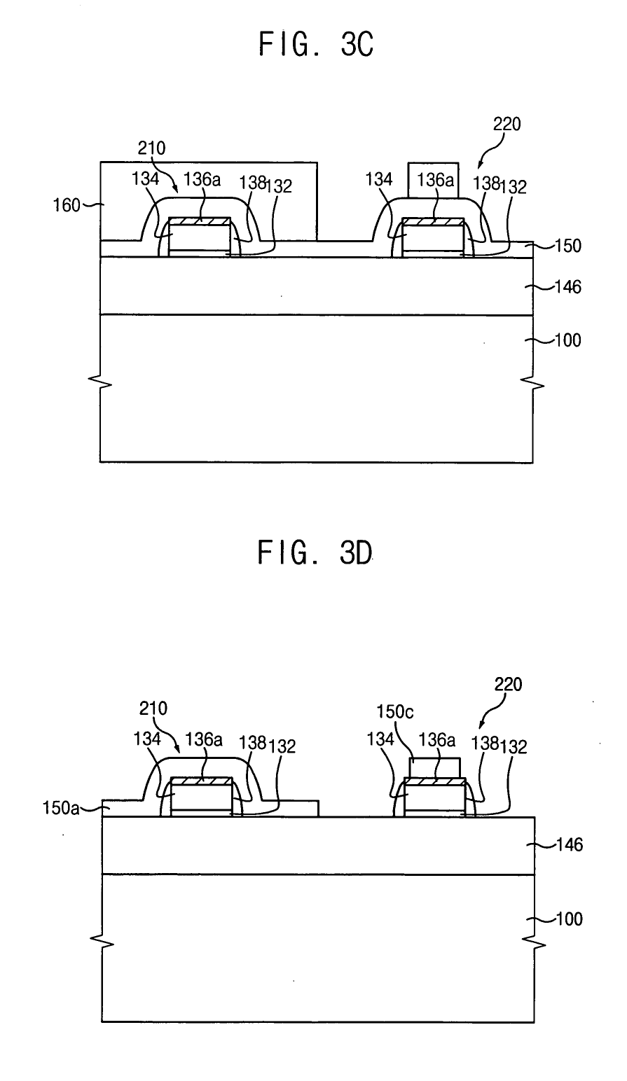

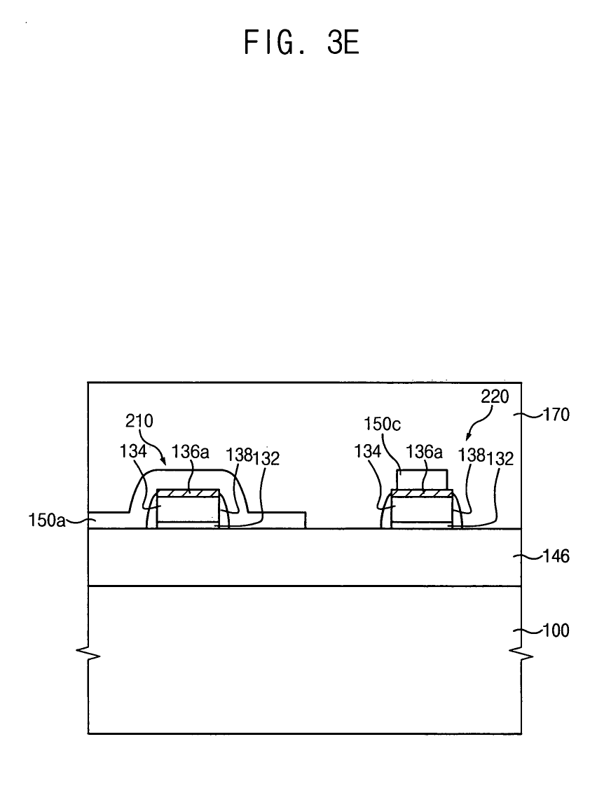

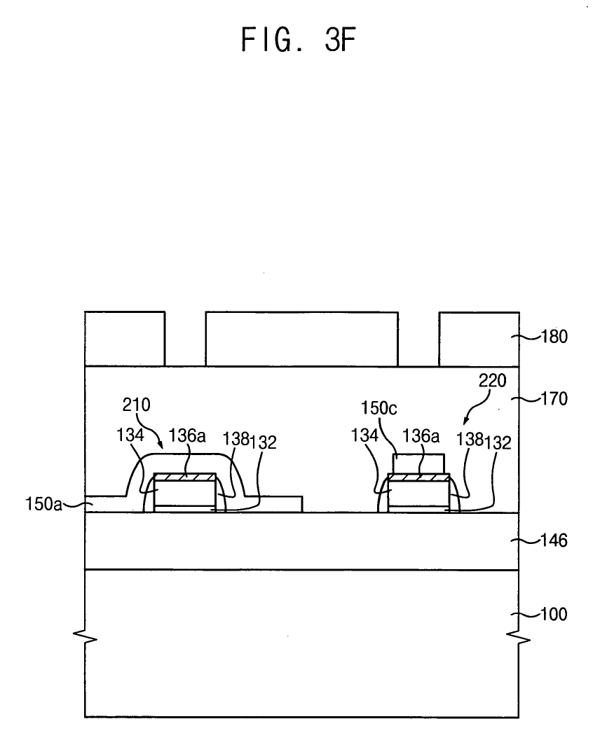

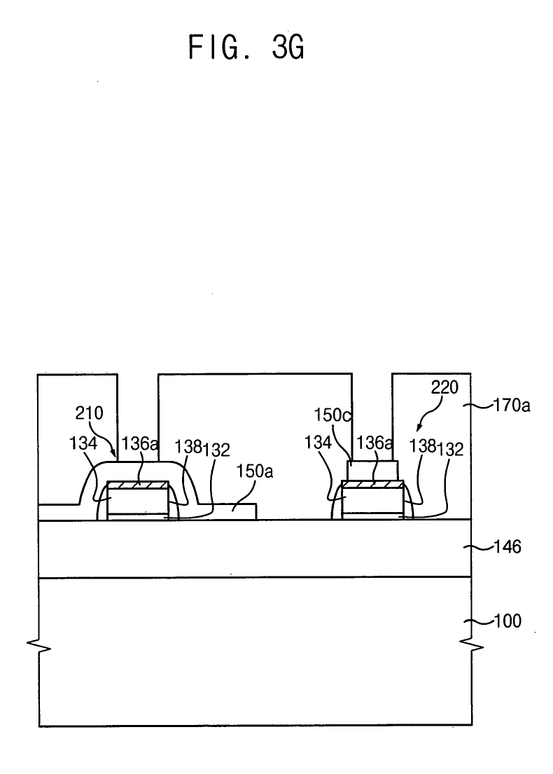

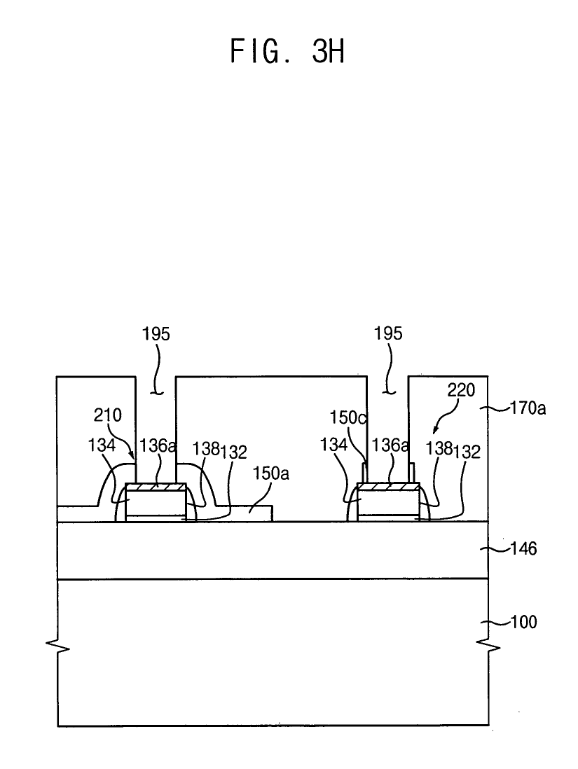

Referring to FIG. 3A, in the field region of the device, a gate structure is formed on the semiconductor substrate 100. The gate structure 200 includes a first gate structure 210 of the NMOS transistor 120 and a second gate structure 220 of the PMOS transistor 130.

Each of the first and second gate structures 210 and 220 includes the gate insulation layer 132 formed on the isolation layer 146, the gate electrode 134 formed on the gate insulation layer 132, the first silicide layer 136a formed on the gate electrode 134, and the side well spacers 138 formed on the sidewall of the gate electrode 134.

Referring to FIG. 2B, a first insulation layer 150 is formed by a plasma-enhanced chemical vapor deposition (PECVD) on the NMOS transistor 120, the PMOS transistor 130 and the isolation layer 146. Examples of materials of which the first insulation layer is formed 150 include silicon nitride, silicon oxynitride, silicon carbide, silicon carbon nitride or a combination thereof. Also, the first insulation layer 150 can have a thickness of about 300 Å to about 700 Å.

Here, the first insulation layer 150 corresponds to a layer having a compressive stress. The first insulation layer 150 having the compressive stress beneficially applies a tensile stress to the channel region 142 of the NMOS transistor 120 to improve mobility of electrons serving as carriers of the NMOS transistor 120, thereby increasing the driving current in the NMOS transistor 120.

On the contrary, in the PMOS transistor, the first insulation layer 150 having the compressive stress detracts from the operation and performance of the PMOS-transistor, because it decreases the driving current in the PMOS transistor. The tensile stress in the PMOS transistor is applied to the channel region 142 of the PMOS transistor 130.

Referring to FIG. 3B, the channel region does not exist under the first and second gate structures 210 and 220 so that the above-mentioned effect caused by the first insulation layer 150 having the compressive stress is not generated.

Referring to FIGS. 2C and 3C, a first photoresist pattern 160 is formed on the first insulation layer 150 to partially expose the first insulation layer 150 through the first photoresist pattern 160.

Referring to FIG. 2D, the first insulation layer 150 is etched using the first photoresist pattern 160 as an etching mask to form a first insulation layer pattern including a first portion 150a that entirely covers the NMOS transistor 120, and a second portion 150b that is partially positioned on the PMOS transistor 130. The first portion 150a of the first insulation layer pattern has the compressive stress and also functions as an etch stop layer in forming a contact hole. The second portion 150b of the first insulation layer pattern only functions as an etch stop layer in forming a contact hole that is later formed through a second silicide layer 136b in the PMOS transistor 130. The first photoresist pattern 160 is then removed.

Here, since a portion of the first insulation layer 150 formed around the gate electrode 134 of the PMOS transistor 130 is removed, the channel region 142 under the gate electrode 134 of the PMOS transistor 130 is not influenced by the tensile stress caused by the first insulation layer 150. Thus, reduction of the driving current in the PMOS transistor 130 is prevented.

Referring to FIG. 3D, the first portion 150a of the first insulation layer pattern is formed on the first gate structure 210. Also, a third portion 150c of the first insulation layer pattern is formed on the second gate structure 220.

The semiconductor substrate 100 having the first, second and third portions 150a, 150b and 150c of the first insulation layer pattern is annealed at a temperature of about 500° C. to about 1,000° C. The annealed first portion 150a of the first insulation layer pattern may concentratedly apply the tensile stress to the channel region 142 of the NMOS transistor 120. The semiconductor substrate 100 may be annealed by a rapid thermal process (RTP) or by using furnace equipment.

Referring to FIGS. 2E and 3E, a second insulation layer 170 including oxide is formed on the semiconductor substrate 100 having the first insulation layer pattern.

Referring to FIGS. 2F and 3F, a second photoresist pattern 180 is formed on the second insulation layer 170 to partially expose the second insulation layer 170 through the second photoresist pattern 180.

Referring to FIGS. 2G and 3G, the second insulation layer 170 is partially etched using the second photoresist pattern 180 as an etching mask to form a second insulation layer pattern 170a having a critical dimension of no more than about 0.15 μm. The second photoresist pattern 180 is then removed.

Referring to FIG. 2H, the first and second portions 150a and 150b of the first insulation layer pattern are partially etched using the second insulation layer pattern 170a as an etching mask to form first contact holes 190 exposing the second silicide layer 136b that is formed in the source/drain regions 140a and 140b.

Referring to FIG. 3H, the second and third portions 150b and 150c of the first insulation layer pattern are partially etched using the second insulation layer pattern 170a as an etching mask to form a second contact hole 195 exposing the first silicide layer 136a on the gate electrode 134.

As a result, the CMOS device having the NMOS transistor 120 and the PMOS transistor 130 is completed. The CMOS device has the first insulation layer pattern that includes the first portion 150a having the beneficial compressive stress that increases the driving current and functioning as the etch stop layer in the NMOS transistor 120, and the second portion 150b functioning as the etch stop layer in the PMOS transistor 130.

According to the present invention, the CMOS device has the first insulation layer pattern that includes the first portion having the compressive stress and functioning as the etch stop layer in the NMOS transistor, and the second portion functioning as the etch stop layer in the PMOS transistor. Therefore, the contact hole may be readily formed in the PMOS transistor with the benefit of the etch stop layer without reducing the driving current. Also, the contact hole may be readily formed and the driving current may be increased in the NMOS transistor.

While this invention has been particularly shown and described with references to preferred embodiments thereof, it will be understood by those skilled in the art that various changes in form and details may be made herein without departing from the spirit and scope of the invention as defined by the appended claims.

1. A method of forming a CMOS device comprising:
forming first and second conductive structures on a substrate;
forming an insulation layer on the substrate having the first and second conductive structures; and
patterning the insulation layer to form an insulation layer pattern having a first portion on the first conductive structure and a second portion on the second conductive structure, the first portion having a compressive stress and functioning as an etch stop layer, and the second portion functioning as an etch stop layer.

2. The method claim 1, further comprising annealing the insulation layer pattern.

3. The method of claim 2, wherein the insulation layer pattern is annealed by a rapid thermal process.

4. The method of claim 2, wherein the insulation layer pattern is annealed at a temperature of about 500° C. to about 1,000° C.

5. The method of claim 1, wherein the insulation layer comprises silicon nitride, silicon oxynitride, silicon carbide, silicon carbon nitride or a combination thereof.

6. The method of claim 1, wherein the insulation layer has a thickness of about 300 Å to about 700 Å.

7. The method of claim 1, wherein forming the insulation layer pattern comprises:
forming a photoresist pattern on the insulation layer to partially expose the insulation layer; and
partially etching the insulation layer using the photoresist pattern as an etching mask to form the insulation layer pattern.

8. The method of claim 1, wherein the first conductive structure corresponds to an NMOS transistor, and the second conductive structure corresponds to a PMOS transistor.

9. A method of forming a CMOS device comprising:
forming first and second conductive structures on a substrate;
forming a first insulation layer on the substrate having the first and second conductive structures;
patterning the first insulation layer to form a first insulation layer pattern having a first portion on the first conductive structure and a second portion on the second conductive structure, the first portion having a compressive stress and functioning as an etch stop layer, and the second portion functioning as an etch stop layer;
forming a second insulation layer on the substrate having the first insulation layer pattern;
patterning the second insulation layer to form a second insulation layer pattern partially exposing the first insulation layer pattern; and
etching the first insulation layer pattern using the second insulation layer pattern as an etching mask to form a contact hole.

10. The method claim 9, after forming the first insulation layer pattern, further comprising annealing the first insulation layer pattern.

11. The method of claim 10, wherein the first insulation layer pattern is annealed by a rapid thermal process.

12. The method of claim 10, wherein the first insulation layer pattern is annealed at a temperature of about 500° C. to about 1,000° C.

13. The method of claim 9, wherein the first insulation layer comprises silicon nitride, silicon oxynitride, silicon carbide, silicon carbon nitride or a combination thereof.

14. The method of claim 9, wherein the first insulation layer has a thickness of about 300 Å to about 700 Å.

15. The method of claim 9, wherein forming the first insulation layer pattern comprises:
forming a photoresist pattern on the first insulation layer to partially expose the first insulation layer; and
partially etching the first insulation layer using the photoresist pattern as an etching mask to form the first insulation layer pattern.

16. The method of claim 9, wherein the second insulation layer pattern has a critical dimension of no more than about 0.15 μm.
